(19) United States
(12) Patent Application Publication
(10) Pub. No.: US 2004/0119131 A1
(43) Pub. Date: Jun. 24, 2004

(54) Physical vapor deposition on targets comprising Ti and Zr; and methods of use

(76) Inventor: Stephen P. Turner, Moon, PA (US)

Correspondence Address: David G Latwesen, Wells St. John, 601 West First Ave, Suite 1300, Spokane, WA, 99201, US

(21) Appl. No.: 10/276,281

(22) PCT Filed: Jun. 1, 2001
(86) PCT No.: PCT/US01/17670

(51) Int. Cl. H01L 31/108; C23C 14/32

(52) U.S. Cl. 257/486; 204/298.13; 204/298.12; 204/192.17; 257/471

(57) ABSTRACT

The invention described herein relates to physical vapor deposition targets comprising both Ti and Zr. The targets can comprise a uniform texture across the target surface and throughout the thickness; and can further have an increased mechanical strength compared to high purity titanium and tantalum. The sputtering targets can be utilized to sputter deposit a thin film; and such film can be utilized as a copper barrier layer.

### TECHNICAL FIELD

The invention pertains to physical vapor deposition (PVD) targets (such as sputtering targets) comprising titanium and zirconium. The targets can have fine grain sizes and uniform texture. The invention also pertains to methods of inhibiting copper diffusion into substrates.

### BACKGROUND OF THE INVENTION

In the semiconductor; .industry the shift from aluminum and its alloys to copper and its alloys is causing new barrier layer materials to be developed. In aluminum technology TIN is used as a barrier material, and in copper technology TaN is currently the preferred choice. However, tantalum metal is very expensive, and in today's market is not readily available. Also, tantalum sputtering targets with a mean grain size of less than 20 μm are not readily available in the industry today. Tantalum is also known to have problems associated with texture uniformity within sputtering targets. These texture non-uniformities can result in sputter deposition problems; such as variations in deposition rates throughout the target life, and film uniformity problems. A cheaper and more readily available alternative to Ta is therefore desired. A preferred alternative material is one which can be manufactured with a fine grain size and uniform texture; and which can be sputtered to generate few particles and form a uniform film. An additionally desired attribute of future semiconductor sputtering targets is increased mechanical strength, due to larger target sizes and higher sputtering powers, (>20kW). High purity Ti and Ta targets do not generally have sufficient mechanical strength and high temperature stability to prevent target warpage during sputtering, and associated undesirable thin film properties resulting from sputter-deposition of material from a warped target.

To aid in interpretation of this disclosure, it is to be understood that when the term “uniform” is utilized to refer to texture, it is referring to a texture which is predominantly one texture across the target surface and throughout the target thickness.

### SUMMARY OF THE INVENTION

The invention described herein relates to physical vapor deposition targets comprising titanium and zirconium; and having fine grain sizes. Preferably, the targets also comprise a uniform texture across the target surface and throughout the thickness. More preferably, the targets also have an increased mechanical strength compared to high purity titanium and tantalum. Grain size can be an important target parameter, and yet grain size can also be difficult to control in sputtering targets.

The invention also pertains to methods of forming sputtering targets, and to methods of utilizing sputtering targets to form;orm thin films comprising Ti and Zr (with the term “thin film” referring to a film having a thickness of less than or equal to 500 angstroms).

Additionally, the invention pertains to structures and methods wherein materials comprising Ti and Zr are utilized as barriers to copper diffusion.

### BRIEF DESCRIPTION OF THE DRAWINGS

Preferred embodiments of the invention are described below with reference to the following accompanying drawings.

FIG. 1 is a diagrammatic, cross-sectional view of an exemplary target construction encompassed by the present invention.

FIG. 2 is a micrograph of a Ti-5at% Zr sputtering target material with a beta phase +martensite microstructure, ancI having an average grain size of 74 microns.

FIG. 3 is a micrograph of a Ti-5at% Zr sputtering target material with an alpha phase microstructure, and having an average grain size of 13.3 microns.

FIG. 4 is a diagrammatic, cross-sectional view of a semiconductor construction comprising a barrier layer formed in accordance with methodology of the present invention.

FIG. 5 is a micrograph of a Ti-5 at%A Zr sputtering target material with a predominantly beta phase microstructure, and having an average grain size of 8.8 μm.

FIG. 6 is a micrograph of a Ti-1 at% Zr sputtering target with a predominantly alpha phase microstructure, and with an average grain size of 27.2 μm.

### DETAILED DESCRIPTION OF THE PREFERRED EMBODIMENTS

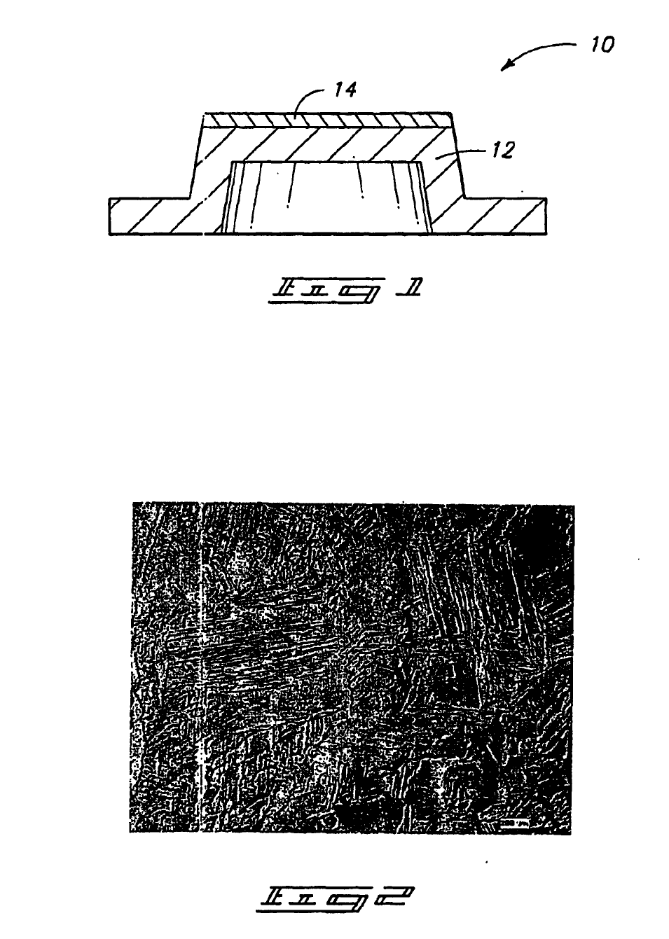

In particular aspects, the invention pertains to sputtering target constructions. Sputtering targets encompassed by the present invention can have any of numerous geometries, with an exemplary geometry being a so-called ENDURA™ target of the type available from Honeywell Electronics, Inc. An exemplary BNDURA™ target construction 10 is shown in FIG. 1 to comprise a backing plate 12 and a target 14. Target construction 10 is shown in cross-sectional view in FIG. 1, and would typically comprise a circular outer periphery if viewed from the top. Although target construction 10 is shown to comprise the backing plate 12 supporting the target 14, it is to be understood that the invention also encompasses monolithic target constructions (i.e., target constructions in which the entirety of a construction is target material) and other planar and non-planar target designs.

Sputtering target constructions of the present invention comprise alloys of titanium and zirconium (i.e., Ti/Zr alloys). Alloys of titanium and zirconium can be used to replace tantalum for barrier and other applications. Titanium and zirconium can be alloyed together to form a single phase solid solution across the whole Ti-Zr binary composition range; and such can be desirable in sputtering target constructions. The addition of zirconium to a titanium-comprising material can form a resulting material having increased mechanical strength relative to the initial titanium-comprising material (and also having increased mechanical strength relative to a high-purity tantalum material). The resulting Ti/Zr material can thus be more suitable for high power sputtering operations than was the initial titanium-comprising material (and better for sputtering operations than a high purity tantalum material). Additionally, the resulting Ti/Zr material can be sputtered to form films having improved properties relative to films formed by sputtering the initial titanium-comprising material. Also, the films formed from the Ti/Zr material can also have improved properties relative to films formed from high purity tantalum materials.

The relative amounts of Ti and Zr in an alloy of a target can be controlled to tailor particular properties of the target, and to tailor particular properties of films formed by physical vapor deposition from the target. For instance the crystal lattice parameters of an hcp crystal structure within a target can be tailored by adjusting relative amounts of Ti and Zr. Such can enable a film to be sputter-deposited from the target with tailored lattice properties. For instance, the film can be tailored to have lattice properties which more closely match the lattice parameters of adjacent films (relative to a match that would be obtained from high-purity titanium) to improve adhesion and other properties. The a and c lattice parameters of a Ti/Zr crystal structure can be changed by, for example, 8-10 % with appropriate adjustment of the relative amount of Ti: and Zr. Similar lattice parameter changes can be induced in the nitride forms of the cubic TiZrN crystal structures. Furthermore, the control of lattice parameters through composition can also be used to control sputter target textures and improve target sputtering characteristics; such as, for example, film uniformity and step coverage.

Ti and Zr both have the same crystal-structure (hcp) at room temperature and also form nitrides with the same cubic structure. Ti and Zr have a different atomic radii (by about 8%), and therefore the addition of Zr to Ti (or, conversely, the addition of Ti to Zr) can influence recrystallization and grain growth of the alloys and their respective nitride films (generally, the recrystallization and grain growth are both inhibited by either addition of Ti to Zr or addition of Zr to Ti).

Films formed by sputter deposition from targets comprising alloys of Ti and Zr can have good barrier properties for Cu diffusion. Furthermore, since Ti and Zr are completely soluble in each other (and thus form a solid solution across all compositions), a sputtering target can be formed with any composition in the Ti-Zr phase diagram and still have a single phase, uniform composition throughout. Films formed by sputter deposition from targets comprising, consisting essentially of, or consisting of Ti and Zr can comprise, consist essentially, or consist of Ti and Zr. Further, if the films arm formed by sputter deposition in a nitrogen-comprising atmosphere, or an atmosphere comprising oxygen and nitrogen; the films can comprise, consist of, or consist essentially of Ti and Zr in combination with nitrogen or both oxygen and nitrogen.

An alloy of Ti and Zr can be thenno-mechanically processed to achieve a fully recrystallized fine grain size target (with an average grain size throughout the target being less than 500 μm) which is desired to produce highly uniform film thickness sought by the semiconductor industry. Furthermore, the addition of Zr to Ti results in an alloy with increased mechanical strength and hardness (see Table 1), which can be beneficial in sputtering targets and sputtered films formed from the targets. For instance, the data shown in Table l evidences that a Ti/Zr target encompassed by the present invention can have a tensile strength of at least 50 ksi (with 1 ksi equaling 1 000lbs/in²), at least 75 ksi, or even at least 100 ksi.

TABLE 1
Mechanical Properties of Ti-Zr alloys compared to pure Ti and Ta

| | | Vickers | Ultimate Tensile | 0.2% Yield |
|---|---|---|---|---|
| Material | Grain Size (μm) | Hardness | Strength (ksi) | Strength (ksi) |
| Pure Ta | 50 | 84.8 | 42.5 | 33.6 |
| Pure Ti | 15 | 110.2 | 30.7 | 22.6 |
| Ti 1 at % Zr | 10.3 | 160.6 | 59.3 | 50.2 |
| Ti-5 at % Zr | 8.8 | 201.5 | 77.8 | 68.0 |
| Ti-35 at % Zr | Martensite | 345.0 | 110-150 | 90-130 |

Another advantage of utilizing Ti-Zr alloys in sputtering targets is that Ti-Zr alloys have higher recrystallization temperatures and are therefore more thermally stable than pure Ti, making the Ti-Zr alloys more suitable for high power sputtering applications (with “high power sputtering applications” being sputter applications utilizing a power greater than 20 kW).

In one aspect of the invention, an ingot comprising Ti and Zr (or in some embodiments consisting essentially of Ti and Zr; and in some other embodiments consisting of Ti and Zr) is made by vacuum melting. The vacuum melting can include one or more of vacuum induction melting (VIM), vacuum arc remelting (VAR) or electron-beam (e-beam) melting techniques. Preferably, the resulting ingot has a substantially uniform composition throughout. Further, the solidification times utilized in forming the ingot are preferably minimized to limit the amount of compositional segregation in the solid phase.

In particular aspects of the invention, an ingot is formed of a material consisting essentially of, or consisting of, Ti and Zr; with such material comprising from about 0.05 at% to about 99.95 at% Zr. Preferably the Zr concentration is from about 0.05 at% to about 10 at%. More preferably, the Zr concentration is from about 0.05 at% to 5 at%; and even more preferably the Zr concentration is from about 0.05 at% to about 2 at%. If compositional uniformity is particularly desired, the congruent composition of Ti with 39.5±3at% Zr can be chosen.

The ingot is mechanical deformed at a sufficiently high temperature to reduce the chances of cracking, but yet at a temperature low enough to cause breakup and refinement of the ingot's grain structure. For alloys which contain >20wt% Zr, it can be preferred to keep the ingot material under an inert atmosphere during heating to alleviate or avoid oxidation of the ingot material. The mechanical deformation of the ingot material should preferably include more than 40% total strain before final recrystallization of the material. The deformation of the ingot material can be accomplished utilizing one or more of several methods, including, for example, forging, rolling, and equal-channel angular extrusion (ECAE).

Final recrystallization of the ingot material is preferably conducted below the alpha to beta transformation temperature, and preferably while the material is under an inert atmosphere if temperatures exceeding 400° C. are used, (with the term “inert” referring to an atmosphere that does not react with the Ti/Zr material at the recrystallization temperature).

Grain size reduction and control of a material comprising Ti and Zr can be accomplished by the above-described methods; and further grain size reduction and control can be achieved by cycling the material through the alpha to beta phase transformation temperature. Such cycling can take advantage of a martenisitic phase transformation to initiate new grains.

Methodology of the present invention can form a material having an overall mean grain size of less than or equal to 500 μm, less than or equal to 100 μm, less than or equal to 50 μm, less than or equal to 20 μm, and even less than or equal to 10 μm. Furthermore, mean grain sizes of less than 5 μm can be achieved with careful control of thermo-mechanical deformation techniques and processing temperatures.

In particular embodiments, a process of the present invention can comprises the following steps:

1. Vacuum cast an ingot of Ti and Zr, (multiple melting operations may be desired to improve chemical homogeneity);

2. Hot isostatically press or hot forge/roll the ingot at a temperature above the recrystallization temperature to remove internal casting defects;

3. Plastically deform the material to break up any prior existing ingot structure (plastic deformation can be achieved by, but is not limited to, any of the conventional deformation techniques), total deformation should be greater than 40%; and .

4. If a fully recrystallized microstructure is desired, an anneal can be conducted at a temperature and time long enough to cause recrystallization.

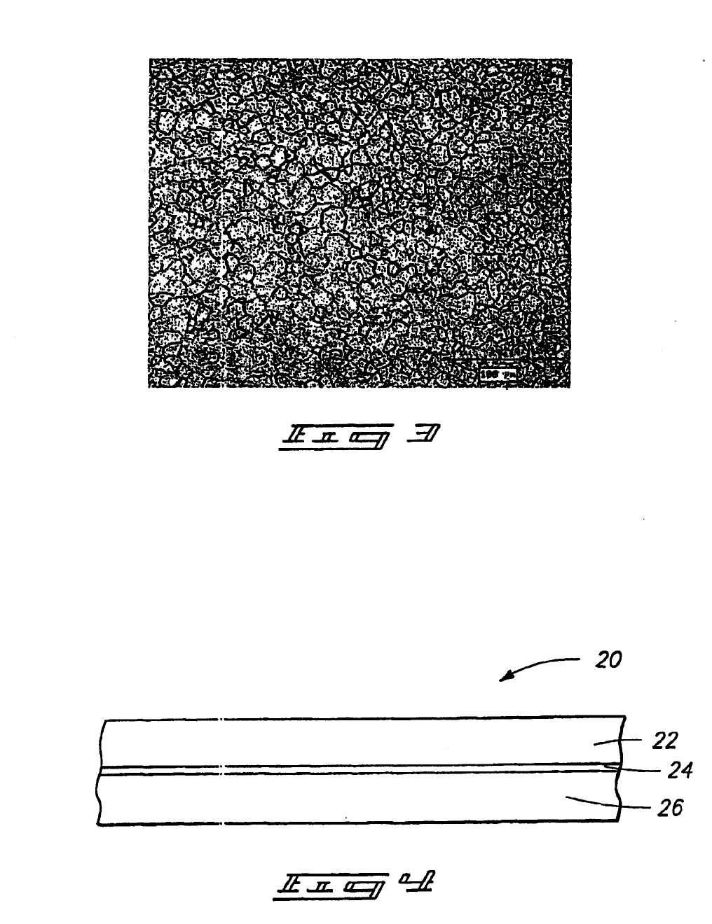

If a material formed by the above-described procedure is annealed at a temperature. above the (at +B) / B transus, the material can have a beta phase, alpha phase or martensite microstructure, or a combination, depending on the cooling rate of the material, see FIG. 2. A more preferable alpha phase microstructure can be achieved if material is annealed at a temperature below the (α+β) /β transus, see FIG. 3.

Sputtering target performance in many materials is influenced by crystallographic texture. In pure titanium it has been reported that various textures perform better than others in certain applications. For instance, some textures can lead to better film uniformity and step coverage from a sputtered-deposited material than can other textures. The ability to change and optimize the strength of desired textures is limited in pure titanium. However the addition of zirconium to titanium can allow target textures to be manipulated to improve, or even optimize, performance of the targets; and can allow textures of thin films deposited from the targets to be manipulated. The crystallographic texture of a titanium/zirconium target material can be controlled by controlling the deformation temperature and direction in the thermo-mechanical processing of a titanium/zirconium material. Additionally, or alternatively, the crystallographic texture can be controlled by controlling the titanium/zirconium composition. Such composition can affect crystallographic lattice parameters that affect the type and dominance of deformation slip systems, which ultimately can dictate the texture of a finished material. Further, crystallographic texture can be controlled by controlling the annealing times and temperatures utilized in processing a Ti/Zr material.

Among the materials which can be produced by methodology of the present invention are targets comprising; consisting essentially of, or consisting of, Ti-Zr with predominantly (103) crystallographic texture; Ti-Zr with predominantly (002) crystallographic texture; and Ti-Zr with predominantly (102) crystallographic texture.

The Ti/Zr materials produced by methodology of the present invention can be utilized as PVD targets and utilized to form thin films of Ti/Zr having predominantly (103) crystallographic texture; predominantly (002) crystallographic texture; or predominantly (102) crystallographic texture. Such thin films can be incorporated into semiconductor applications as, for example, copper barrier layers. Specifically, the thin films can be formed between a material predominately comprising copper and a material to which copper diffusion is to be alleviated or prevented (such as, for example, borophosphosilicate glass). The thin films can then define a barrier layer which alleviates or prevents copper diffusion therethrough. Such is illustrated in FIG. 4, wherein a semiconductor construction 20 is illustrated. Construction 20 includes a copper-containing layer 22; a thin film 24 comprising Ti and Zr; and a material 26 into which copper diffusion is to be alleviated. It is noted that the copper-containing layer can comprise either pure copper, or copper alloys. Construction 20 can be formed over a semiconductive material, such as, for example, a silicon-comprising substrate.

In particular applications, a target of the present invention can consist essentially of Ti and Zr, with the zirconium not being present in the range of 12-18 atom% or the range of 32-38 atom%. However, in other embodiments, such as, for example, when the target is provided specifically for the purpose of sputter depositing a Cu barrier layer, the target can comprise any concentration of Zr of from about 0.05 at% to about 99.95 at%.

To aid in interpretation of the claims that follow, the term “fine grain size” refers to an average grain size of less than or equal to 500 μm; as calculated according to standard ASTM E112 methods.

Also to aid in interpretation of this disclosure, it is to be understood that when the term “predominantly” is utilized to refer to a texture of a material, it is referring to the dominant/major texture of a material. A predominate texture can be less than 50% of the total texture of a material, provided that it is the most abundant texture of the material. Thus, a material comprising 30% (102) texture; 30% (002) texture and 40% (103) texture would have (103) as the predominate crystallographic texture, even though there is less than 50% of the (103) texture present.

Methodology of the present invention can be utilized to form a material having predominate (102); (002) or (103) texture. Although the examples provided herein only show processes which form materials having predominately (103) or (002) textures, persons of ordinary skill in the art will recognize that methodology of the present invention can be additionally utilized to form materials having (102) textures.

### EXAMPLES

Example 1.

A Ti-5at%/ Zr sputtering target (i.e, a target comprising 95 atomic percent Ti and 5 atomic percent Zr) was manufactured according to the following process. Vacuum casting was utilized to form an ingot of Ti-5at% Zr material. The material was then hot isostatically pressed, and subsequently hot forged at a temperature greater than 800° C. with approximately 40% strain. The material was then rolled at a temperature greater than 300 ° C. to oversize thickness, with a total strain exceeding 80%. Finally, the material was annealed at a temperature above the (α+β)/βtransus; air cooled; and flattened.

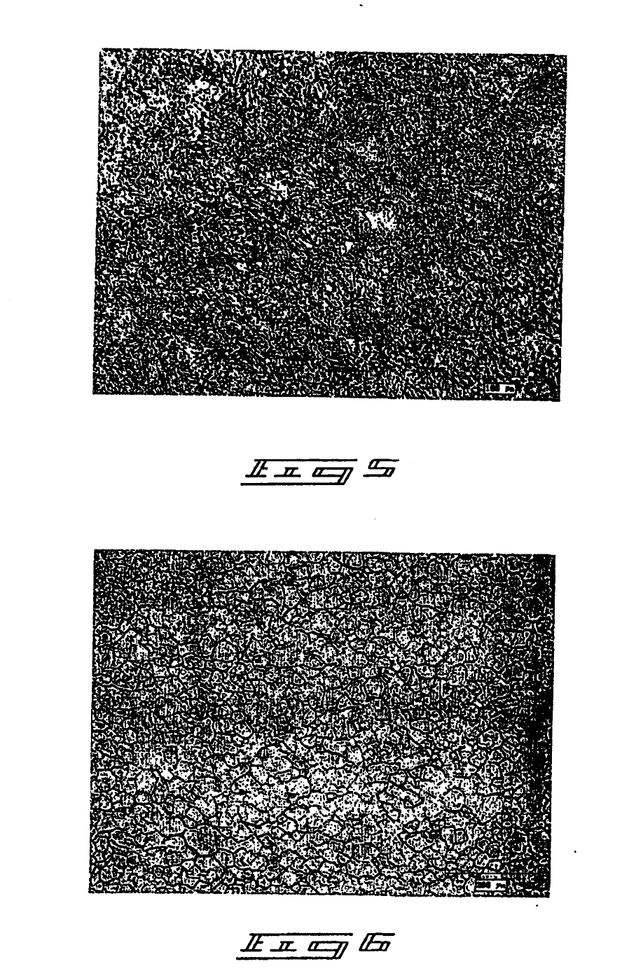

The heat treatment time and temperature for this example were chosen to produce a fine- grained mixed alpha +beta structure, see FIG. 5. The average grain size of the material produced by this exemplary method was found to be 8.8 microns with a predominantly (002) texture, (see Table 2).

Example 2.

A Ti-1at% Zr sputtering target (i.e, a target comprising 99 atomic percent Ti and 5 atomic percent Zr) was manufactured according to the following process. Vacuum casting was utilized to form an ingot of Ti-1at%Zr material. The material was then hot isostatically pressed, and subsequently hot forged at a temperature greater than 400° C. with approximately 40% strain. The material was then rolled at a temperature greater than 300 ° C. to oversize thickness, with a total strain exceeding 80%. Finally, the material was annealed at a temperature below the (α+β)/βtransus; air cooled; and flattened.

The resulting target material was found to have an alpha phase, equiaxed microstructure; with a mean grain size of 27.2 microns and a predominant texture of (103), (see Table 2 and FIG. 6).

Table 2 lists various characterizing aspects of materials formed in accordance with methodologies of the present invention.

TABLE 2
Texture characterization of Ti-Zr alloys after different annealing cycles

| | Micro- | Grain | | | | | | | |
|---|---|---|---|---|---|---|---|---|---|
| | structural | Size | % | % | % | % | % | % | % |
| Alloy | Phase | (μm) | (100) | (002) | (101) | (102) | (110) | (103) | (112) |
| Ti-1 at % Zr | α | 27.2 | 6.6 | 21.9 | 5.7 | 13.0 | 14.7 | 32.6 | 5.5 |
| Ti-1 at % Zr | α + β | 47.4 | 2.1 | 41.9 | 7.7 | 27.9 | 0.0 | 16.4 | 3.9 |
| Ti-1 at % Zr | α | 40.5 | 3.0 | 8.1 | 6.4 | 17.1 | 0.0 | 65.1 | 0.4 |
| Ti-5 at % Zr | α + β | 8.8 | 3.3 | 46.6 | 4.1 | 12.9 | 1.3 | 31.8 | 0.0 |

1. A sputtering target consisting essentially of titanium and zirconium, and comprising predominately (103) crystallographic texture, (102) crystallographic texture or (002) crystallographic texture.

2. The sputtering target of claim I comprising a tensile strength of at least 50 ksi.

3. The sputtering target of claim 1 comprising a tensile strength of at least 75 ksi.

4. The sputtering target of claim 1 comprising a tensile strength of at least 100 ksi.

5. The sputtering target of claim 1 comprising an average grain size of less than or equal to 500 μm.

6. The sputtering target of claim 1 comprising an average grain size of less than or equal to 100 μM.

7. The sputtering target of claim 1 comprising an average grain size of less than or equal. to 50 μm.

8. The sputtering target of claim 1 comprising an average grain size of less than or equal to 20 μm.

9. The sputtering target of claim 1 comprising an average grain size of less tan or equal to 10 μm.

10. The sputtering target of claim 1 wherein the zirconium is not present in the range of 12-18 atom% or the range of 32-38 atom%.

11. The sputtering target of claim 1 comprising from about 0.05 atom% Zr to about 99.95 atom% Zr.

12. The sputtering target of claim 1 comprising from about 0.05 atom% Zr to about 10 atom% Zr.

13. The sputtering target of claim 1 comprising from about 0.05 atom% Zr to about 5 atom% Zr.

14. The sputtering target of claim 1 consisting essentially of Zr and Ti.

15. The sputtering target of claim 1 consisting of Zr and Ti.

16. The sputtering target of claim 1 comprising predominately (103) crystallographic texture.

17. The sputtering target of claim 1 comprising predominately (102) crystallographic texture.

18. The sputtering target of claim 1 comprising predominately (002) crystallographic texture.

19. A sputtering target consisting essentially of titanium and zirconium, and comprising an average grain size of less than or equal to 100 μm.

20. The sputtering target of claim 19 comprising an average grain size of less than or equal. to 50 μm.

21. The sputtering target of claim 19 comprising an average grain size of less than or equal to 20 μm.

22. The sputtering target of claim 19 comprising an average grain size of less than or equal to 10 μm.

23. The sputtering target of claim 19 comprising an average grain size of less than 5 μm.

24. The sputtering target of claim 19 comprising a tensile strength of at least 50 ksi.

25. The sputtering target of claim 19 comprising a tensile strength of at least 75 ksi.

26. The sputtering target of claim 19 comprising a tensile strength of at least 100 ksi.

27. The sputtering target of claim 19 comprising predominately (103) crystallographic texture.

28. The sputtering target of claim 19 comprising predominately (102) crystallographic texture.

29. The sputtering target of claim 19 comprising predominately (002) crystallographic texture.

30. A sputtering target consisting essentially of titanium and zirconium; with the zirconium not being present in the range of 12-18 atom% or the range of 32-38 atom%.

31. The sputtering target of claim 30 comprising from about 0.05 atom% Zr to about 99.95 atom% Zr.

32. The sputtering target of claim 30 comprising from about 0.05 atom% Zr to about 10 atom% Zr.

33. The sputtering target of claim 30 comprising from about 0.05 atom% Zr to about 5 atom% Zr.

34. The sputtering target of claim 30 consisting of Zr and Ti.

35. The sputtering target of claim 30 comprising predominately (103) crystallographic texture.

36. The sputtering target of claim 30 comprising predominately (102) crystallographic texture.

37. The sputtering target of claim 30 comprising predominately (002) crystallographic texture.

38. The sputtering target of claim 30 comprising an average grain size of less than 500μm.

39. The sputtering target of claim 30 comprising an average grain size of less than 100 μm.

40. The sputtering target of claim 30 comprising an average grain size of less than 50 μm.

41. The sputtering target of claim 30 comprising an average grain size of less than 20μm.

42. The sputtering target of claim 41 comprising predominately (103) crystallographic texture.

43. The sputtering target of claim 41 comprising predominately (102) crystallographic texture.

44. The sputtering target of claim 41 comprising predominately (002) crystallographic texture.

45. The sputtering target of claim 30 comprising an average grain size of less than 10 μm

46. The sputtering target of claim 30 comprising an average grain size of less than 5 μm.

47. A barrier layer to impede copper diffusion, the barrier layer consisting essentially of titanium and zirconium in combination with nitrogen, or both of oxygen and nitrogen.

48. The barrier layer of claim 47 consisting of Zr, Ti and N.

49. The barrier layer of claim 47 consisting of Zr, Ti, M and O.

50. The barrier layer claim 47 comprising from about 0.05 atom% Zr to about 99.95 atom% Zr.

51. The barrier layer of claim 47 comprising from about 0.05 atom% Zr to about 10 atom% Zr.
